(19) United States
(12) Patent Application Publication
(10) Pub. No.: US 2013/0278247 A1
(43) Pub. Date: Oct. 24, 2013

(54) ARC POSITION ENCODER WITH AN EXTENDED ANGULAR POSITION SENSING RANGE

(71) Applicants: ShanoPrasad Kunjappan, Bangalore (IN); Dinesh Naik, Bangalore (IN); Madhan Raj Bagianathan, Hosur (IN); Manikandan M., Bangalore (IN)

(72) Inventors: ShanoPrasad Kunjappan, Bangalore (IN); Dinesh Naik, Bangalore (IN); Madhan Raj Bagianathan, Hosur (IN); Manikandan M., Bangalore (IN)

(73) Assignee: HONEYWELL INTERNATIONAL INC., Morristown, NJ (US)

(21) Appl. No.: 13/449,874

(22) Filed: Apr. 18, 2012

(51) Int. Cl. G01B 7/30; G01R 33/07; G01R 33/09

(52) U.S. Cl. 324/207.14; 324/207.25; 324/207.21; 324/207.2

(57) ABSTRACT

Disclosed are techniques for sensing an angular position of a rotating object over a 360-degree angular position range using an arc position encoder comprising a 180-degree angular position sensing range. The encoder may include a base defined by first and second ends, one or more magnetic field sensors disposed within the base between the first and second ends, one or more of first and second base extensions disposed on the first and second ends, and one or more polarity transition sensors disposed within the one or more of the first and second base extensions. The encoder may further include a magnetic target having first and second magnetic poles disposed on opposite ends so as to generate a uniform magnetic field, wherein the magnetic target is coupled to the rotating object so as to rotate about an axis of rotation located in a center of a circle defined by the base.

### TECHNICAL FIELD

This disclosure relates to position encoders, and more particularly, to techniques for using a position encoder to sense an angular position of a rotating object.

### BACKGROUND

Position encoders are among a number of electro-mechanical transducers that may be used to sense a position of an object. Position encoders may be configured to sense an actual, or “absolute,” position of an object, as well as a “relative” position, or a displacement, of the object. Furthermore, a position encoder may comprise any of a wide variety of linear and angular, or “rotary,” position encoders. In some examples, position encoders may use contact-based sensing means to sense a position of an object by mechanically coupling the object to the position encoder, e.g., to a movable member or a rotating shaft of the position encoder, which may be mechanically coupled to a sensing element of the position encoder. In other examples, position encoders may employ a wide variety of contactless sensing means, such as optical, magnetic, capacitive, and inductive means, as some examples. Position encoders employing such contactless sensing means may be less susceptible to wear and may provide greater durability compared to contact-based position encoders.

As one example, a linear position encoder may sense a position of an object moving along a linear trajectory relative to the linear position encoder. For example, the linear position encoder may sense a position of an encoder “read-head” that is coupled to the object relative to an encoder track as the encoder read-head and the object move together along the encoder track. The position of the read-head relative to the encoder track may be sensed using mechanical, optical, magnetic, capacitive, or inductive means, as well as using other sensing means.

As another example, an angular, or rotary, position encoder may sense an angular position of an object that is rotating about an axis of rotation relative to the angular position encoder. For example, in the case of the angular position encoder employing magnetic sensing means, as described above, the angular position encoder may sense an angular position of a magnetic target that is coupled to the rotating object relative to one or more magnetic field sensors disposed within a base of the angular position encoder. The magnetic target may be disposed at a center of the base so as to generate a uniform magnetic field which varies from the perspective of the one or more magnetic field sensors based on the angular position of the magnetic target relative to the sensors. In this example, the one or more magnetic field sensors may include magnetoresistive (MR) sensors, Hall-Effect sensors, or other magnetic sensors.

### SUMMARY

In general, this disclosure describes techniques for using an arc position encoder to sense an angular position of a rotating object over an extended angular position range. For example, the arc position encoder may comprise a 180-degree angular position sensing range. The techniques of this disclosure may, in some cases, enable extending the 180-degree sensing range of the arc position encoder, e.g., by incorporating additional structural and functional elements into the arc position encoder, such that the arc position encoder may be used to sense an angular position of a rotating object over a 360-degree angular position range.

In one example, an angular position sensing system for sensing an angular position of a rotating object over a 360-degree angular position range includes an arc position encoder comprising a 180-degree angular position sensing range, wherein the arc position encoder includes a base comprising an arc length defined by a first end and a second end of the base, one or more magnetic field sensors disposed within the base between the first and second ends, one or more of a first base extension disposed on the first end, wherein the first base extension extends from the first end, and a second base extension disposed on the second end, wherein the second base extension extends from the second end, one or more polarity transition sensors disposed within the one or more of the first and second base extensions, and a magnetic target comprising a first magnetic pole and a second magnetic pole disposed on opposite ends of the magnetic target so as to generate a uniform magnetic field, wherein the magnetic target is coupled to the rotating object so as to rotate about an axis of rotation located in a center of a circle defined by the base, and wherein, at any given time, one of the first and second magnetic poles is located within the 180-degree angular position sensing range of the arc position encoder, and another one of the first and second magnetic poles is located outside of the 180-degree angular position sensing range.

In another example, a method of sensing an angular position of a rotating object over a 360-degree angular position range using an arc position encoder comprising a 180-degree angular position sensing range includes receiving one or more polarity transition signals from one or more polarity transition sensors disposed on one or more of a first end and a second end of a base of the arc position encoder, the one or more polarity transition signals indicating a transition of one of a first magnetic pole and a second magnetic pole of a magnetic target coupled to the rotating object so as to rotate about an axis of rotation located in a center of a circle defined by the base, wherein the first and second magnetic poles are disposed on opposite ends of the magnetic target so as to generate a uniform magnetic field, into the 180-degree angular position sensing range of the arc position encoder, and another one of the first and second magnetic poles out of the 180-degree angular position sensing range, receiving one or more proximity signals from one or more magnetic field sensors disposed within the base between the first and second ends, the one or more proximity signals indicating relative proximity of the one of the first and second magnetic poles within the 180-degree angular position sensing range of the arc position encoder to each of the one or more magnetic field sensors, and determining the angular position of the rotating object within the 360-degree angular position range based at least in part on the one or more polarity transition signals and the one or more proximity signals.

The details of one or more examples are set forth in the accompanying drawings and the description below. Other features, objects, and advantages in addition to those described below will be apparent from the description and drawings, and from the claims.

### BRIEF DESCRIPTION OF DRAWINGS

FIG. 1 is a block diagram that illustrates one example of an angular position sensing system, consistent with the techniques of this disclosure.

FIG. 2 is a conceptual diagram that illustrates a front view of one example of an arc position encoder which may be used in conjunction with the example angular position sensing system of FIG. 1, consistent with the techniques of this disclosure.

FIG. 3 is a conceptual diagram that illustrates a perspective view of the example arc position encoder of FIG. 2, consistent with the techniques of this disclosure.

FIG. 4 is a flow diagram that illustrates one example of a method of sensing an angular position of a rotating object over a 360-degree angular position range using an arc position encoder comprising a 180-degree angular position sensing range, consistent with the techniques of this disclosure.

### DETAILED DESCRIPTION

In general, this disclosure describes techniques for using an arc position encoder to sense an angular position of a rotating object over an extended angular position range. For example, the arc position encoder may comprise a 180-degree angular position sensing range. As described in greater detail below, the techniques of this disclosure may, in some cases, enable extending the 180-degree sensing range of the arc position encoder, e.g., by incorporating additional structural and functional elements into the arc position encoder, such that the arc position encoder may be used to sense an angular position of a rotating object over a 360-degree angular position range.

An angular, or “rotary,” position encoder may sense an angular position of an object that is rotating about an axis of rotation relative to the angular position encoder. For example, in the case of the angular position encoder employing magnetic sensing techniques, the angular position encoder may sense an angular position of a magnetic target that is coupled to the rotating object relative to one or more magnetic field sensors disposed within a base of the angular position encoder. The magnetic target may be disposed at a center of the base so as to generate a uniform magnetic field which varies from the perspective of the one or more magnetic field sensors based on the angular position of the magnetic target relative to the sensors. For example, the one or more magnetic field sensors may include magnetoresistive (MR) sensors, Hall-Effect sensors, or other magnetic sensors.

Existing angular position encoders, and, in particular, those employing magnetic sensing techniques, are generally configured to sense an angular position of a rotating object in one of a 180-degree and a 360-degree angular position range. For example, an angular position encoder configured to sense angular position of a rotating object over a 180-degree angular position range may comprise a 180-degree, or “arc” position encoder, which may include an arc base and one or more magnetic field sensors, e.g., MR sensors, or other sensors, disposed within the arc base. Alternatively, an angular position encoder configured to sense angular position of a rotating object over a full 360-degree angular position range may comprise a relatively more complex 360-degree, or “full-range,” position encoder, which may include a circular base and one or more magnetic field sensors disposed within the circular base. In some examples, the circular base may require relatively more magnetic field sensors than the arc base of the arc position encoder in order to enable sensing the angular position of the rotating object over the 360-degree angular position range.

Accordingly, existing techniques for using angular position encoders to sense angular position of rotating objects include using full-range position encoders to sense angular position of rotating objects over a 360-degree range, as well as arc position encoders to sense angular position of rotating objects over a 180-degree range. Additionally, existing techniques may include combining multiple, e.g., two, arc position encoders to sense angular position of rotating objects over a 360-degree range. Furthermore, as previously described, full-range angular position encoders may require relatively more complex hardware, e.g., a circular base and a greater number of magnetic field sensors disposed within the circular base, as well as more complex processing of output signals of the magnetic field sensors, compared to arc position encoders. In contrast, arc position encoders may require relatively less complex hardware, e.g., an arc base and fewer magnetic field sensors disposed within the arc base, as well as less complex signal processing, compared to full-range angular position encoders. However, arc position encoders may have a limited angular position sensing range, i.e., a 180-degree angular position sensing range, as explained above.

As previously described, the techniques of this disclosure may, in some cases, enable extending a 180-degree sensing range of an arc position encoder. As one example consistent with the techniques described herein, the arc position encoder may include, in addition to one or more magnetic field sensors disposed within a base of the arc position encoder, one or more polarity transition sensors disposed within one or more base extensions of the base. For example, the one or more base extensions may be disposed on one or more ends of the base. According to the techniques, the one or more polarity transition sensors may be configured to sense transitions of opposing magnetic poles of a rotating magnetic target (e.g., North and South magnetic poles disposed on opposite ends of the magnetic target) of the arc position encoder, which may be coupled to the rotating object, into and out of the 180-degree sensing range. For example, at any given time, one of two such opposing magnetic poles may be located within the 180-degree sensing range, while the other of the two opposing magnetic poles may be located outside of the 180-degree sensing range. As such, the one or more polarity transition sensors may be configured to sense transitions of each of the two opposing magnetic poles into and out of the 180-degree sensing range.

Development of the techniques described herein has demonstrated that, in general, opposing magnetic poles of a rotating magnetic target of an arc position encoder produce substantially similar (e.g., symmetrical) responses with respect to one or more magnetic sensing elements disposed within a base of the arc position encoder. This is the case in particular with respect to MR sensors, which may generate substantially similar outputs in response to magnetic fields having a same field angle relative to each of the MR sensors, but opposite field polarities. The techniques of this disclosure may, in some cases, take advantage of the above-described phenomenon in order to extend the 180-degree sensing range of the arc position encoder, as described above.

For example, by sensing the transitions of the two opposing magnetic poles using the one or more polarity transition sensors in the manner described above, the arc position encoder may be configured to determine which of the two opposing magnetic poles is present within the 180-degree sensing range at any given time. The arc position encoder may be further configured to sense the position of the respective magnetic pole within the 180-degree sensing range (e.g., as the magnetic pole travels through the 180-degree sensing range) using the one or more magnetic field sensors. For example, the one or more magnetic field sensors may sense relative proximity of the respective magnetic pole to each of the one or more magnetic field sensors.

In some examples, the angular position of the respective magnetic pole within the 180-degree sensing range may correspond to an angular position of the rotating object coupled to the magnetic target within a corresponding 180-degree sub-range of the 360-degree angular position range. In this manner, for the two opposing magnetic poles described above, two such 180-degree sub-ranges may be defined within the 360-degree angular position range. Furthermore, because the two opposing magnetic poles are conventionally disposed on opposite ends of the magnetic target, as also described above, the two 180-degree sub-ranges may be 180-degrees out of phase with respect to one another. In other words, the two 180-degree sub-ranges may be consecutive and non-overlapping within the 360-degree angular position range, i.e., each 180-degree sub-range may comprise one half of the full 360-degree angular position range. As such, the arc position encoder may be configured to sense the angular position of each of the two opposing magnetic poles within the 180-degree sensing range when the respective magnetic pole is present within the sensing range, which may correspond to the angular position of the rotating object within each of the two 180-degree sub-ranges, or, collectively, within the full 360-degree angular position range.

As explained above, the techniques of this disclosure may, in some cases, effectively extend the 180-degree sensing range of the arc position encoder to encompass the 360-degree angular position range. As a result, the arc position encoder may be configured to sense the angular position of the magnetic target, and thereby the rotating object, over the extended 360-degree angular position range. In this manner, the techniques of this disclosure may reduce the complexity of angular position encoders used to sense angular position of rotating objects over a 360-degree angular position range, while requiring minimal additional structural and functional hardware and components, and signal processing resources.

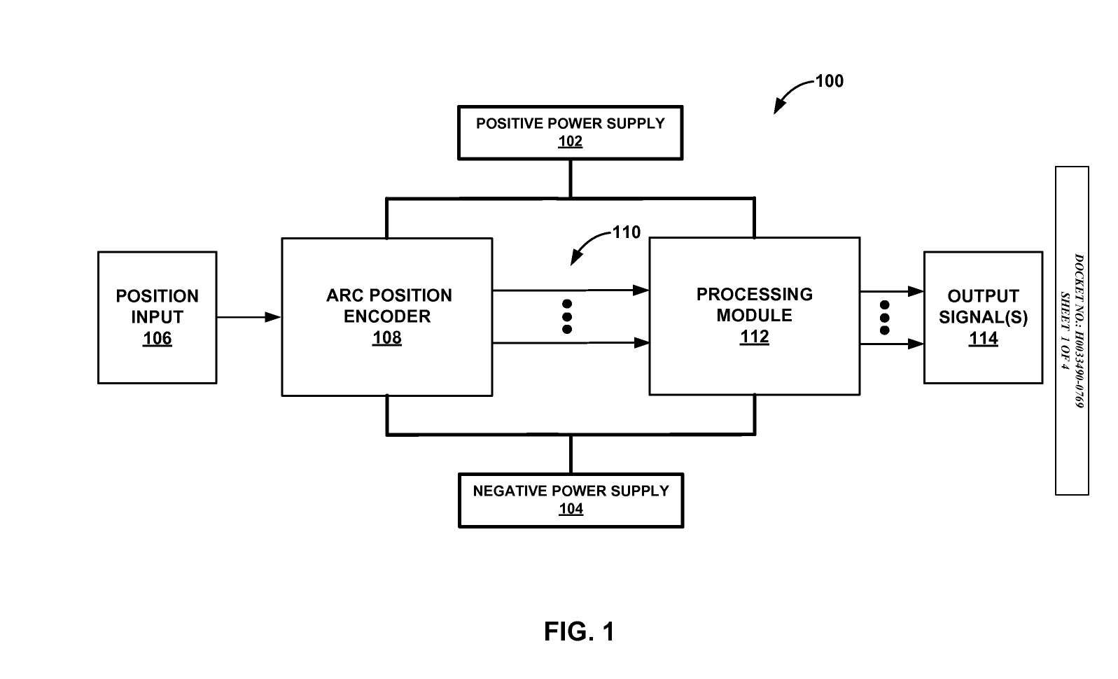

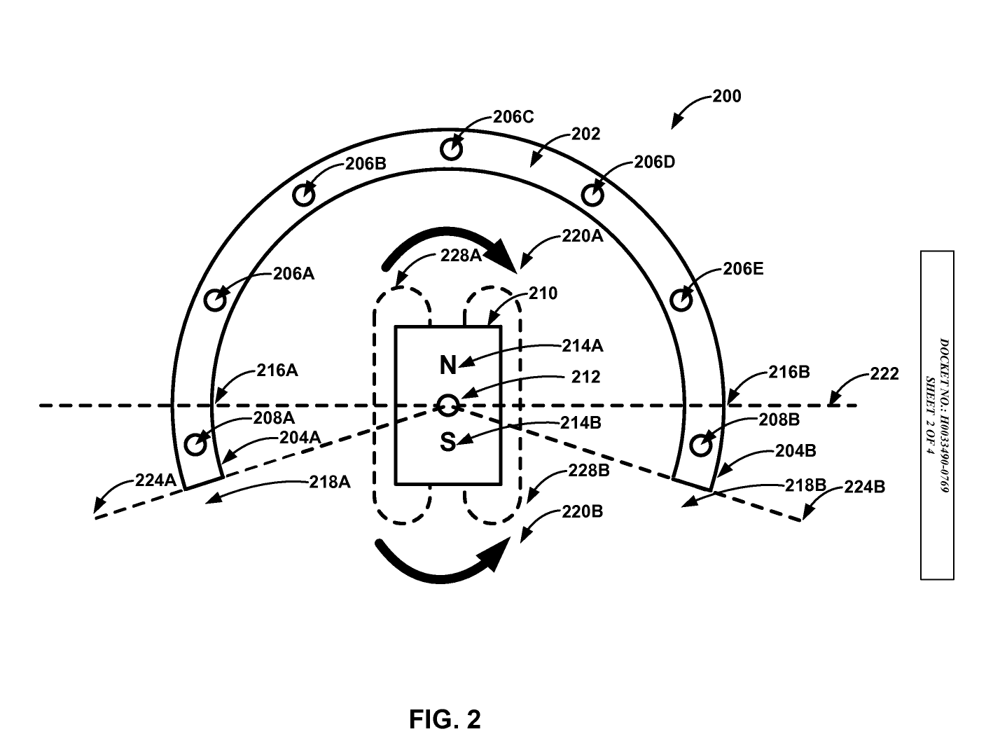

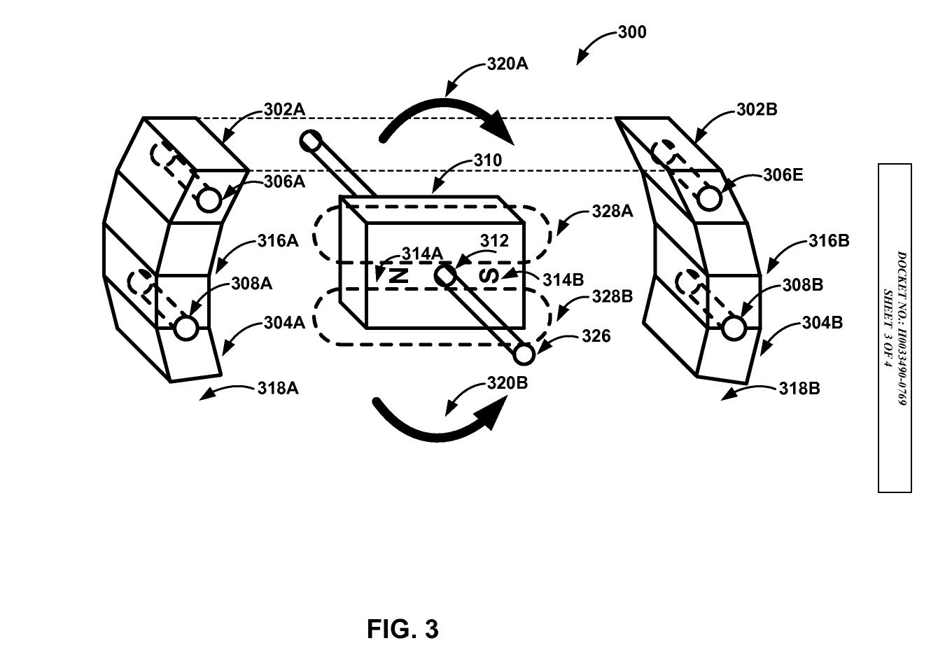

FIG. 1 is a block diagram that illustrates one example of an angular position sensing system 100, consistent with the techniques of this disclosure. As shown in FIG. 1, system 100 includes a positive power supply 102, a negative power supply 104, a position input 106, an arc position encoder 108, one or more arc position encoder output signal(s) 110, a processing module 112, and one or more processing module output signal(s) 114. System 100 may comprise an electro-mechanical system or device of any kind, including any combination of mechanical structural components and hardware, electro-mechanical transducers, discrete electronic components, digital and/or analog circuitry, and mechanical and electronic sub-systems or sub-devices of any kind. Examples of processing module 112 are described in greater detail below. Examples of arc position encoder 108 are also described in greater detail below, as well as with reference to arc position encoders 200 and 300 of FIGS. 2 and 3, respectively.

In the example of FIG. 1, position input 106 may comprise an angular position of a rotating object (not shown) within a 360-degree angular position range relative to arc position encoder 108. In other words, position input 106 may represent a physical angular position of the rotating object within the 360-degree angular position range, relative to arc position encoder 108. For example, the rotating object may be configured to rotate about an axis of rotation located in a center of a circle defined by a base or arc position encoder 108, as will be described in greater detail below with reference to FIGS. 2 and 3. In some examples, the rotating object may comprise any of a variety of rotating shafts, gears, or wheels. In other examples, the rotating object may comprise another object that rotates about the axis or rotation.

System 100, and in particular, arc position encoder 108, may be configured to convert position input 106 from an angular position of the rotating object to one or more electrical signals in order to generate arc position encoder output signal(s) 110. For example, arc position encoder output signal(s) 110 may comprise one or more voltage and/or current signals indicative of position input 106, i.e., of the angular position of the rotating object within the 360-degree angular position range relative to arc position encoder 108. Furthermore, processing module 112 may be configured to process arc position encoder output signal(s) 110 to generate processing module output signal(s) 114. Processing module output signal(s) 114 may comprise any combination of analog and/or digital signals or other information used to represent the angular position of the rotating object within the 360-degree angular position range. As one example, processing module output signal(s) 114 may comprise one or more values indicative of the exact angular position of the rotating object within the 360-degree angular position range (e.g., one or more values between 0 and 360 degrees, or 0 to 2π radians). As another example, processing module output signal(s) 114 may comprise one or more values indicative of an angular position of the rotating object within a subset (e.g., a 180-degree sub-range) of the 360-degree angular position range (e.g., one or more values between 0 and 180 degrees, or 0 to π radians), as well as one or more values indicative of the subset itself (e.g., one or more values indicating a first or a second 180-degree sub-range). In any case, processing module 112 may process arc position encoder output signal(s) 110 (e.g., filter, scale, normalize, level-shift, combine, etc.) in any manner to generate processing module output signal(s) 114.

Processing module 112 may comprise any suitable arrangement of hardware, software, firmware, or any combination thereof, to perform the techniques attributed to processing module 112 in this disclosure. In general, processing module 112 may include any of one or more microprocessors, microcontrollers, digital signal processors (DSPs), application specific integrated circuits (ASICs), field programmable gate arrays (FPGAs), or any other equivalent integrated or discrete logic circuitry, as well as any combination of such components. Furthermore, processing module 112 may include various types of analog circuitry, in addition to, or in place of, the logic devices and circuitry described above.

Additionally, positive power supply 102 and negative power supply 104 may each comprise any power supply unit, module, or circuitry also included within system 100, which may, in some examples, be integrated with arc position encoder 108 and/or processing module 112 within a common enclosure, or on a common printed circuit board (PCB). Although positive power supply 102, negative power supply 104, position input 106, arc position encoder 108, arc position encoder output signal(s) 110, processing module 112, and processing module output signal(s) 114 of system 100 are described as separate units or modules for conceptual purposes, in some examples, any combination of these components of system 100 may be functionally integrated within a common enclosure or housing.

Additionally, in this disclosure, any reference made to a memory, or a memory device, used to store instructions, data, or other information, includes any volatile or non-volatile media, such as random access memory (RAM), read only memory (ROM), non-volatile RAM (NVRAM), electrically erasable programmable ROM (EEPROM), flash memory, and the like. In some examples, one or more memory devices may be external to system 100 and/or processing module 112, for example, external to an enclosure or a common PCB used to enclose or house system 100 and/or processing module 112. In other examples, the one or more memory devices may be internal to system 100 and/or processing module 112, e.g., included within a common enclosure or on a common PCB.

According to the techniques of this disclosure, as one example, system 100, including arc position encoder 108 and processing module 112, may be configured to sense an angular position of a rotating object over a 360-degree angular position range. As previously described, the rotating object may comprise any of a variety of rotating shafts, gears, or wheels. For example, arc position encoder 108 may comprise a 180-degree angular position sensing range. In this example, arc position encoder 108 may include a base comprising an arc length defined by a first end and a second end of the base, and one or more magnetic field sensors disposed within the base between the first and second ends. For example, the arc length of the base may correspond to the 180-degree angular position sensing range of arc position encoder 108. Furthermore, the one or more magnetic field sensors may comprise one or more MR sensors, or other magnetic sensors.

Also in this example, arc position encoder 108 may further include one or more of a first base extension disposed on the first end, wherein the first base extension extends from the first end, and a second base extension disposed on the second end, wherein the second base extension extends from the second end. For example, each of the one or more of the first and second base extensions may be configured to extend from the respective one of the first and second ends in a direction that substantially follows a circumference of a circle defined by the base. As one example, each of the one or more of the first and second base extensions may be configured to extend from the respective one of the first and second ends so as to extend the arc length of the base beyond the arc length defined by the first and second ends. Additionally, arc position encoder 108 may include one or more polarity transition sensors disposed within the one or more of the first and second base extensions. For example, the one or more polarity transition sensors may comprise one or more MR sensors, Hall-Effect sensors, or other magnetic sensors. As one example, the polarity transition sensors of the one or more polarity transition sensors disposed within each of the one or more of the first and second base extensions may include one or more MR sensors, as well as one or more Hall-Effect sensors.

Furthermore, arc position sensor 108 may still further include a magnetic target comprising a first magnetic pole and a second magnetic pole disposed on opposite ends of the magnetic target so as to generate a uniform magnetic field. For example, the first and second magnetic poles may each comprise one or more North (N) and South (S) magnetic poles of the magnetic target. In this example, the magnetic target may be coupled to the rotating object so as to rotate about an axis of rotation located in a center of the circle defined by the base.

Also in this example, at any given time, one of the first and second magnetic poles may be located within the 180-degree angular position sensing range of arc position encoder 108, and another one of the first and second magnetic poles may be located outside of the 180-degree angular position sensing range. Stated another way, one of the first and second magnetic poles may be located between 0 and 180 degrees of the 360-degree angular position range, while the other one of the first and second magnetic poles may be located between 180 and 360 degrees of the 360-degree angular position range, at any given time.

In this manner, angular position sensing system 100 of FIG. 1 represents an example of an angular position sensing system for sensing an angular position of a rotating object over a 360-degree angular position range, the system comprising an arc position encoder comprising a 180-degree angular position sensing range, wherein the arc position encoder includes a base comprising an arc length defined by a first end and a second end of the base, one or more magnetic field sensors disposed within the base between the first and second ends, one or more of a first base extension disposed on the first end, wherein the first base extension extends from the first end, and a second base extension disposed on the second end, wherein the second base extension extends from the second end, one or more polarity transition sensors disposed within the one or more of the first and second base extensions, and a magnetic target comprising a first magnetic pole and a second magnetic pole disposed on opposite ends of the magnetic target so as to generate a uniform magnetic field, wherein the magnetic target is coupled to the rotating object so as to rotate about an axis of rotation located in a center of a circle defined by the base, and wherein, at any given time, one of the first and second magnetic poles is located within the 180-degree angular position sensing range of the arc position encoder, and another one of the first and second magnetic poles is located outside of the 180-degree angular position sensing range.

FIG. 2 is a conceptual diagram that illustrates a front view of one example of an arc position encoder 200 which may be used in conjunction with the example angular position sensing system 100 of FIG. 1, consistent with the techniques of this disclosure. In other words, arc position encoder 200 represents one example of arc position encoder 108 depicted in FIG. 1.

As shown in FIG. 2, arc position encoder 200 includes a base 202 comprising an arc length defined by a first end 216A and a second end 216B of base 202, one or more magnetic field sensors 206A-206E disposed within base 202 between first and second ends 216A, 216B, one or more of a first base extension 204A disposed on first end 216A, wherein first base extension 204A extends from first end 216A, and a second base extension 204B disposed on second end 216B, wherein second base extension 204B extends from second end 216B, one or more polarity transition sensors 208A and 208B disposed within the one or more of first and second base extensions 204A, 204B, and a magnetic target 210 comprising a first magnetic pole 214A and a second magnetic pole 214B disposed on opposite ends of magnetic target 210 so as to generate a uniform magnetic field 228A and 228B.

In the example of FIG. 2, base 202 may comprise part of an enclosure or housing of arc position encoder 200. Furthermore, arc position encoder 200 may be configured to be mounted, via base 202, within another structure, such as a system (e.g., system 100 of FIG. 1) enclosure or housing, or a system chassis. In some examples, base 202 may further include one or more mounting holes or couplings (not shown), which may be used to mount base 202 within the structure or chassis.

As can be seen in FIG. 2, each of first and second base extensions 204A, 204B may extend from the respective one of first and second ends 216A, 216B in a direction that substantially follows a circumference of a circle defined by base 202. As one example, each of first and second base extensions 204A, 204B may be configured to extend from the respective one of first and second ends 216A, 216B so as to extend the arc length of base 202 beyond the arc length defined by first and second ends 216A, 216B. For example, as depicted in FIG. 2, first and second base extensions 204A, 204B may extend from first and second ends 216A, 216B to a first extension end 218A and a second extension end 218B, respectively. The arc length by which first and second base extensions 204A, 204B extend the arc length of base 202 beyond the arc length defined by first and second ends 216A, 216B is defined by positions of first and second extension ends 218A, 218B relative to first and second ends 216A, 216B, and may comprise any arc length. In other words, the arc length of each of first and second base extensions 204A, 204B may comprise any arc length. Furthermore, the arc lengths of first and second base extensions 204A, 204B may be different. Additionally, in some cases, arc position encoder 200 may include only one of first and second base extensions 204A, 204B. In any case, as shown in FIG. 2, the angular distance corresponding to the arc length of each of first and second base extensions 204A, 204B relative to the center of the circle defined by base 202 may be indicated by axis 222, axis 224A, and axis 224B.

As one example, in a case where the arc length of each of first and second base extensions 204A, 204B described above corresponds to an angular distance (as indicated by axis 222, axis 218A, and axis 218B) of 10-degrees, thereby adding a total of 20-degrees to the physical angular range of base 202 of 180-degrees, arc position encoder 200 may be referred to as a 200-degree arc position encoder. In this example, the physical angular range of base 202 (i.e., 180-degrees) and the angular distances corresponding to the arc lengths of first and second base extensions 204A, 204B (i.e., 10-degrees each, or 20-degrees collectively), are added to determine a total physical angular range of arc position encoder 200 (i.e., 200-degrees). In other examples, arc position encoder 200 may comprise a different (e.g., a smaller, or a larger) total physical angular range.

In some examples consistent with the techniques of this disclosure, the arc length and the corresponding angular distance of each of one or more of first and second base extensions 204A, 204B may be selected so as to correspond to an angular position sensing range of a single magnetic field sensor of magnetic field sensors 206A-206E (e.g., 10-degrees). For example, magnetic field sensors 206A-206E may be substantially uniformly spaced within base 202 between first and second ends 216A, 216B, such that each magnetic field sensor of magnetic field sensors 206A-206E is configured to sense relative proximity of one of first and second magnetic poles 214A, 214B located within the 180-degree angular position sensing range of arc position encoder 200 to the respective magnetic field sensor. As such, an angular position sensing range of a particular magnetic field sensor of magnetic field sensors 206A-206E may be a sub-set (e.g., 10-degrees) of the 180-degree sensing range of arc position encoder 200, and may be defined by the number and relative placement (e.g., a uniform spacing) of magnetic field sensors 206A-206E within base 202. In the examples described above, the arc length and the corresponding angular distance of each of first and second base extensions 204A, 204B may also correspond to this angular position sensing range of a particular magnetic field sensor of magnetic field sensors 206A-206E (e.g., 10-degrees).

Moreover, the one or more polarity transition sensors 208A and 208B may be disposed within the one or more of first and second base extensions 204A, 204B, e.g., at a center of the arc length, corresponding to a mid-point within the angular distance, of a particular base extension. In other examples, the arc lengths and corresponding angular distances of first and second base extensions 204A, 204B may be selected using other parameters and considerations. Furthermore, the one or more polarity transition sensors 208A and 208B may be disposed within the one or more of first and second base extensions 204A, 204B at different locations.

Additionally, in the example of FIG. 2, magnetic target 210 may be coupled to a rotating object (also not shown) using beam coupling 212 disposed within magnetic target 210, as shown in FIG. 2. Beam coupling 212 may comprise any of a wide variety of thread couplings, clamp couplings, or other types of couplings. For example, the rotating object, such as a rotating shaft, gear, or wheel, may be coupled to magnetic target 210 via beam coupling 212 so as to rotate together with magnetic target 210 about an axis of rotation located in the center of the circle defined by base 202. In the example of FIG. 2, the location of the axis of rotation may coincide with the location of beam coupling 212, such that the axis of rotation passes through beam coupling 212 and extends in an inward/outward direction (i.e., in and out of the page) relative to the front view of arc position encoder 200. For example, the rotating object and magnetic target 210 may rotate about the axis of rotation in one of a clockwise direction of rotation 220A and a counterclockwise direction of rotation 220B relative to base 202, as also shown in FIG. 2.

As also shown in FIG. 2, as magnetic target 210 rotates in one of clockwise direction of rotation 220A and counterclockwise direction of rotation 220B relative to base 202, magnetic field sensors 206A-206E may be configured to sense magnetic field 228A, 228B generated by magnetic target 210. For example, magnetic field sensors 206A-206E may be configured to sense relative proximity of one of first and second magnetic poles 214A, 214B located within the 180-degree angular position sensing range of arc position encoder 200 to each of magnetic field sensors 206A-206E, as explained in greater detail below. Additionally, polarity transition sensors 208A, 208B may be configured to sense transitions of each of first and second magnetic poles 214A, 214B into and out of the 180-degree sensing range, as also explained in greater detail below. In other examples, magnetic field sensors 206A-206E and polarity transition sensors 208A, 208B each may comprise more or fewer sensors.

According to the techniques of this disclosure, in one example, arc position encoder 200 may be included within an angular position sensing system (e.g., system 100 of FIG. 1) for sensing an angular position of a rotating object (not shown) over a 360-degree angular position range. In this example, arc position encoder 200 may comprise a 180-degree angular position sensing range. For example, arc position encoder 200 may include base 202 comprising an arc length defined by first end 216A and second end 216B of base 202, one or more magnetic field sensors 206A-206E disposed within base 202 between first and second ends 216A, 216B, one or more of first base extension 204A disposed on first end 216A, wherein first base extension 204A extends from first end 216A, and second base extension 204B disposed on second end 216B, wherein second base extension 204B extends from second end 216B, one or more polarity transition sensors 208A, 208B disposed within the one or more of first and second base extensions 204A, 204B, and magnetic target 210 comprising first magnetic pole 214A and second magnetic pole 214B disposed on opposite ends of magnetic target 210 so as to generate uniform magnetic field 228A, 228B. In this example, magnetic target 210 may be coupled to the rotating object so as to rotate about an axis of rotation located in a center of a circle defined by base 202. Also in this example, at any given time, one of first and second magnetic poles 214A, 214B may be located within the 180-degree angular position sensing range of arc position encoder 200, and another one of first and second magnetic poles 214A, 214B may be located outside of the 180-degree angular position sensing range.

As another example, magnetic field sensors 206A-206E may be configured to sense relative proximity of the one of first and second magnetic poles 214A, 214B located within the 180-degree angular position sensing range of arc position encoder 200 to each magnetic field sensor of magnetic field sensors 206A-206E. For example, each of magnetic field sensors 206A-206E may be configured to sense the one of first and second magnetic poles 214A, 214B located within the 180-degree angular position sensing range as the one of first and second magnetic poles 214A, 214B passes the respective one of magnetic field sensors 206A-206E, and generate an output signal indicative of a position of the one of first and second magnetic poles 214A, 214B relative to the respective one of magnetic field sensors 206A-206E. In this example, the position indicated by the output signal generated by each of magnetic field sensors 206A-206E may comprise an angular position of the one of first and second magnetic poles 214A, 214B over a sub-range, e.g., a 10-degree sub-range, of the 180-degree sensing range of arc position encoder 200, that corresponds to the respective one of magnetic field sensors 206A-206E, and which may be referred to as an angular position sensing range of the respective one of magnetic field sensors 206A-206E.

As explained in greater detail below, a processing module (e.g., processing module 112 of FIG. 1) may be configured to combine the output signals generated by each of magnetic field sensors 206A-206E to generate one or more common output signals (e.g., processing module output signal(s) 114 of FIG. 1). For example, the one or more common output signals may indicate an angular position of each of first and second magnetic poles 214A, 214B over the 180-degree sensing range of arc position encoder 200, when the respective one of first and second magnetic poles 214A, 214B is present within the 180-degree sensing range.

In this example, to generate the one or more common output signals, the processing module may be configured to combine (e.g., level-shift) the angular position of each of first and second magnetic poles 214A, 214B over the 180-degree sensing range to determine the angular position of the rotating object over the 360-degree angular position range. In addition, the processing module may be further configured to process one or more of the angular position of each of first and second magnetic poles 214A, 214B over the 180-degree sensing range, such as by performing any of a variety of filtering, level-shifting or translation, or other types of signal processing or conditioning. Finally, to generate the one or more common output signals, the processing module may be still further configured to linearize one or more of the angular position of each of first and second magnetic poles 214A, 214B over the 180-degree sensing range and the angular position of the rotating object over the 360-degree angular position range, e.g., using the techniques described in commonly owned U.S. Pat. No. 7,030,604, or any other techniques applicable to linearization of output signals from a plurality of magnetic sensors (e.g., a magnetic sensor array). In other words, the one or more common output signals may comprise a linearized signal indicative of the angular position of the rotating object over the 360-degree angular position range. Finally, the processing module may be configured to output the one or more common output signals, and/or store the one or more common output signals in the one or more memories, or memory devices, described above with reference to system 100 of FIG. 1.

As still another example, polarity transition sensors 208A, 208B may be configured to sense a transition of one of first and second magnetic poles 214A, 214B into the 180-degree angular position sensing range of arc position encoder 200, and another one of first and second magnetic poles 214A, 214B out of the 180-degree angular position sensing range.

As still another example, each of the one or more of first and second base extensions 204A, 204B may extend from the respective one of first and second ends 216A, 216B in a direction that substantially follows a circumference of the circle defined by base 202. As one example, each of first and second base extensions 204A, 204B may be configured to extend from the respective one of first and second ends 216A, 216B so as to extend the arc length of base 202 beyond the arc length defined by first and second ends 216A, 216B. Alternatively, first and second base extensions 204A, 204B may extend from the respective one of first and second ends 216A, 216B in another direction, e.g., slightly inward or slightly outward from the circle defined by base 202, or in a direction that is substantially tangential relative to the circle.

As still another example, the magnetic field sensors of magnetic field sensors 206A-206E may be substantially uniformly spaced within base 202 between first and second ends 216A, 216B. Alternatively, the magnetic field sensors of magnetic field sensors 206A-206E may be non-uniformly, or otherwise asymmetrically, spaced within base 202 between first and second ends 216A, 216B.

As still another example, magnetic field sensors 206A-206E and polarity transition sensors 208A, 208B may be substantially uniformly spaced within base 202 and the one or more of first and second base extensions 204A, 204B.

As still other examples, each magnetic field sensor of magnetic field sensors 206A-206E may comprise a magnetoresistive (MR) sensor. Alternatively, each magnetic field sensor of magnetic field sensors 206A-206E may comprise a different type of magnetic field sensor. In a similar manner, each polarity transition sensor of polarity transition sensors 208A, 208B may comprise an MR sensor. Alternatively, each polarity transition sensor of polarity transition sensors 208A, 208B may comprise a Hall-Effect sensor. Furthermore, polarity transition sensors 208A, 208B may comprise one or more magnetoresistive (MR) sensors and one or more Hall-Effect sensors. For example, each of polarity transition sensors 208A, 208B may comprise one or more magnetoresistive (MR) sensors and one or more Hall-Effect sensors. In the example of FIG. 2, for each of polarity transition sensors 208A, 208B, one or more magnetoresistive (MR) sensors and one or more Hall-Effect sensors may be disposed within each of first and second base extensions 204A, 204B.

In the examples described above, MR sensors may be used for magnetic sensors 206A-206E, and MR and/or Hall-Effect sensors may be used for polarity transition sensors 208A, 208B. For example, while both MR and Hall-Effect sensors may be used to sense a presence of an external magnetic field (e.g., uniform magnetic field 228A, 228B generated by first and second magnetic poles 214A, 214B of magnetic target 210, as described above and with reference to FIGS. 2 and 3), these sensors differ greatly in their manner of operation.

As one example, an MR sensor may be generally configured to sense a magnitude of an external magnetic field applied to the MR sensor (e.g., until a point of saturation of the MR sensor), as well as an angle of the external magnetic field relative to the MR sensor. For example, the MR sensor may comprise one or more magnetoresistive elements a resistance of each of which changes in response to the angle (and, until the point of saturation, the magnitude) of the external magnetic field relative to the respective magnetoresistive element. For example, the change in resistance of each magnetoresistive element may be proportional to a difference between a direction of a bias current flowing through the element, and an angle of magnetization (which may be referred to as a magnetization vector) of the element by the external magnetic field. In this example, the angle of magnetization of the element by the external magnetic field is a function of the angle at which the external magnetic field is applied relative to the element. In other words, an MR sensor may respond in a similar manner to multiple magnetic fields that are applied to the MR sensor at a same angle, but have different, e.g., opposite, polarities.

In contrast, Hall-Effect sensors may generally be configured to sense a magnitude and a polarity of an external magnetic field applied transversely (i.e., at a particular angle) relative to a direction of a bias current flowing through a sensing element of the Hall-Effect sensor. The Hall-Effect sensor may sense the magnitude and polarity of the external magnetic field by generating a voltage across a dimension of the sensing element which is transverse to each of the direction of the bias current and the direction of the external magnetic field. The magnitude of this voltage (sometimes referred to as a Hall voltage) is proportional to the magnitude of the external magnetic field, and the polarity of the voltage is indicative of the polarity of the external magnetic field. Accordingly, because Hall-Effect sensors may generate an output in response to an external magnetic field that is dependent on a polarity of the external magnetic field, in one embodiment, using one or more MR sensors as magnetic field sensors 206A-206E may be preferred. Alternatively, in other embodiments, magnetic field sensors 206A-206E may comprise other sensors, as described above.

In still other examples, the angular position sensing system may further comprise a processing module (not shown) (e.g., processing module 112 of FIG. 1) configured to determine one or more polarity transition output signals of polarity transition sensors 208A, 208B, determine one or more proximity output signals of magnetic field sensors 206A-296E, and determine the angular position of the rotating object within the 360-degree angular position range, based at least in part on the one or more polarity transition output signals and the one or more proximity output signals.

In some examples, to determine the angular position of the rotating object within the 360-degree angular position range based at least in part on the one or more polarity transition output signals and the one or more proximity output signals, the processing module may be configured to determine whether the angular position of the rotating object within the 360-degree angular position range corresponds to a first or a second 180-degree angular position sub-range of the 360-degree angular position range, based at least in part on the one or more polarity transition output signals, wherein the first and second 180-degree angular position sub-ranges are non-overlapping consecutive angular position sub-ranges within the 360-degree angular position range. In this example, the processing module may be further configured to determine the angular position of the rotating object within the respective one of the first and second 180-degree angular position sub-ranges to which the angular position of the rotating object within the 360-degree angular position range corresponds, based at least in part on the one or more proximity output signals.

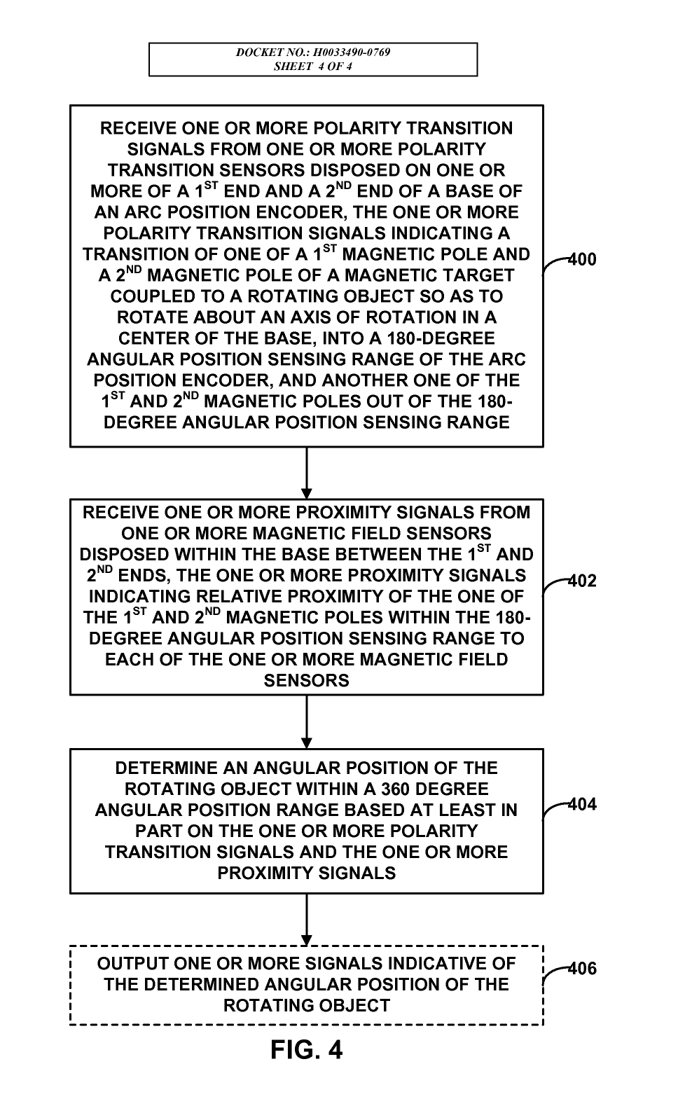

In still other examples, the processing module may be further configured to determine one or more of an angular speed of the rotating object and a direction of angular rotation of the rotating object relative to arc position encoder 200, based at least in part on the determined angular position of the rotating object within the 360-degree angular position range. The particular techniques which may, in some examples, be used by the processing module to make these determinations will be described in greater detail below with reference to FIG. 4.

Finally, the processing module may be further configured to determine a direction of angular rotation of the rotating object relative to arc position encoder 200, based at least in part on the one or more polarity transition output signals. For example, the processing module may be configured to determine, based at least in part on the one or more polarity transition output signals, that a transition of one of first and second magnetic poles 214A, 214B into the 180-degree angular position sensing range of arc position encoder 200, and another one of first and second magnetic poles 214A, 214B out of the 180-degree angular position sensing range, has occurred. As one example, the processing module may be configured to determine the direction of angular rotation of the rotating object based on, e.g., which of first and second magnetic poles 214A, 214B has transitioned into and out of the 180-degree angular position sensing range. As another example, the processing module may be configured to determine the direction of angular rotation of the rotating object based on one or more previously detected transitions (e.g., indications of which may be stored in one or more memory devices within a corresponding angular position sensing system, e.g., system 100) of first and second magnetic poles 214A, 214B into and out of the 180-degree angular position sensing range, and the currently detected transition.

In this manner, arc position encoder 200 of FIG. 2 represents an example of an arc position encoder included within an angular position sensing system for sensing an angular position of a rotating object over a 360-degree angular position range, wherein the arc position encoder comprises a 180-degree angular position sensing range, and wherein the arc position encoder includes a base comprising an arc length defined by a first end and a second end of the base, one or more magnetic field sensors disposed within the base between the first and second ends, one or more of a first base extension disposed on the first end, wherein the first base extension extends from the first end, and a second base extension disposed on the second end, wherein the second base extension extends from the second end, one or more polarity transition sensors disposed within the one or more of the first and second base extensions, and a magnetic target comprising a first magnetic pole and a second magnetic pole disposed on opposite ends of the magnetic target so as to generate a uniform magnetic field, wherein the magnetic target is coupled to the rotating object so as to rotate about an axis of rotation located in a center of a circle defined by the base, and wherein, at any given time, one of the first and second magnetic poles is located within the 180-degree angular position sensing range of the arc position encoder, and another one of the first and second magnetic poles is located outside of the 180-degree angular position sensing range.

FIG. 3 is a conceptual diagram that illustrates a perspective view of the example arc position encoder 200 of FIG. 2, consistent with the techniques of this disclosure. As shown in FIG. 3, arc position encoder 300 includes a base 302A and 302B comprising an arc length defined by a first end 316A and a second end 316B of base 302A, 302B, one or more magnetic field sensors 306A and 306E disposed within base 302A, 302B between first and second ends 316A, 316B, one or more of a first base extension 304A disposed on first end 316A, wherein first base extension 304A extends from first end 316A, and a second base extension 304B disposed on second end 316B, wherein second base extension 304B extends from second end 316B, one or more polarity transition sensors 308A and 308B disposed within the one or more of first and second base extensions 304A, 304B, and a magnetic target 310 comprising a first magnetic pole 314A and a second magnetic pole 314B disposed on opposite ends of magnetic target 310 so as to generate a uniform magnetic field 328A and 328B.

In the example of FIG. 3, base 302A, 302B is depicted using two sections (i.e., 302A, 302B) for purposes of illustrating arc position encoder 300 in greater detail. It should be understood that base 302A, 302B comprises a single base, e.g., base 202 of FIG. 2, and that, although not shown in FIG. 3, the sections of base 302A, 302B are joined to form a single base (e.g., base 302) above the break-out dashed lines located above base 302A, 302B. Additionally, the perspective view of arc position encoder 300 depicts only two magnetic field sensors, i.e., magnetic field sensors 306A and 306E. It should also be understood that arc position encoder 300 may comprise one or more (e.g., 3, 4, 5, etc.) magnetic field sensors, e.g., 206A-206E, as described with reference to FIG. 2, disposed within base 302A, 302B between first and second ends 316A, 316B. Similarly, each of polarity transition sensors 308A, 308B may comprise one or more polarity transition sensors.

Furthermore, magnetic field sensors 306A, 306E and polarity transition sensors 308A, 308B, depicted as each having a cylindrical geometry, are depicted as having a same geometry for purposes of illustration only. As explained above with reference to FIG. 2, each of magnetic field sensors 306A, 306B and polarity transition sensors 308A, 308B may comprise a same type of sensor, e.g., an MR sensor, or another type of sensor, and each of polarity transition sensors 308A, 308B may comprise one or more MR sensors and/or a Hall-Effect sensors, or one or more other sensors, in some examples.

Also, in the example of FIG. 3, magnetic target 310 is coupled to a rotating shaft 326 via beam coupling 312 disposed within magnetic target 310. In some examples, rotating shaft 326 may be coupled to a rotating object (not shown). In other examples, rotating shaft 326 may itself be a rotating object, or part of a rotating object. Beam coupling 312 may comprise any of a wide variety of thread couplings, clamp couplings, or other types of couplings. In any case, the rotating object may be coupled to magnetic target 310 via beam coupling 312 so as to rotate together with magnetic target 310 about an axis of rotation located in a center of a circle defined by base 302A, 302B. In the example of FIG. 3, the location of the axis of rotation may coincide with the location of beam coupling 312, such that the axis of rotation passes through beam coupling 312 and extends in an inward/outward direction relative to a front view of arc position encoder 300, as explained above with reference to arc position encoder 200 of FIG. 2. For example, the rotating object and magnetic target 310 may rotate about the axis of rotation in one of a clockwise direction of rotation 320A and a counterclockwise direction of rotation 320B relative to base 302A, 302B, as also shown in FIG. 3. In the example of FIG. 3, magnetic target 310 is rotated 90-degrees in counterclockwise direction of rotation 320B relative to magnetic target 210 as depicted in FIG. 2.

In this manner, arc position encoder 300 of FIG. 3 represents an example of an arc position encoder included within an angular position sensing system for sensing an angular position of a rotating object over a 360-degree angular position range, wherein the arc position encoder comprises a 180-degree angular position sensing range, and wherein the arc position encoder includes a base comprising an arc length defined by a first end and a second end of the base, one or more magnetic field sensors disposed within the base between the first and second ends, one or more of a first base extension disposed on the first end, wherein the first base extension extends from the first end, and a second base extension disposed on the second end, wherein the second base extension extends from the second end, one or more polarity transition sensors disposed within the one or more of the first and second base extensions, and a magnetic target comprising a first magnetic pole and a second magnetic pole disposed on opposite ends of the magnetic target so as to generate a uniform magnetic field, wherein the magnetic target is coupled to the rotating object so as to rotate about an axis of rotation located in a center of a circle defined by the base, and wherein, at any given time, one of the first and second magnetic poles is located within the 180-degree angular position sensing range of the arc position encoder, and another one of the first and second magnetic poles is located outside of the 180-degree angular position sensing range.

FIG. 4 is a flow diagram that illustrates one example of a method of sensing an angular position of a rotating object over a 360-degree angular position range using an arc position encoder comprising a 180-degree angular position sensing range, consistent with the techniques of this disclosure. The techniques of FIG. 4 may generally be performed by any processing unit or processor, whether implemented in hardware, software, firmware, or a combination thereof, and when implemented in software or firmware, corresponding hardware may be provided to execute instructions for the software or firmware. For purposes of example, the techniques of FIG. 4 are described with respect to angular position sensing system 100 (FIG. 1), arc position encoder 108 (FIG. 1), 200 (FIG. 2), and 300 (FIG. 3), and processing module 112 (FIG. 1), as well as various components thereof, although it should be understood that other systems or devices may be configured to perform similar techniques. Moreover, the steps illustrated in FIG. 4 may be performed in a different order or in parallel, and additional steps may be added and certain steps omitted, without departing from the techniques of this disclosure.

In one example, a processing module (e.g., 112) of an angular position sensing system (e.g., 100) that includes the processing module and an arc position encoder (e.g., 108, 200, and 300) may be configured to sense an angular position of a rotating object over a 360-degree angular position range using the arc position encoder. In this example, the arc position encoder may comprise a 180-degree angular position sensing range.

For example, the processing module may initially receive one or more polarity transition signals from one or more polarity transition sensors disposed on one or more of a first end and a second end of a base of the arc position encoder, the one or more polarity transition signals indicating a transition of one of a first magnetic pole and a second magnetic pole of a magnetic target coupled to the rotating object so as to rotate about an axis of rotation located in a center of a circle defined by the base, wherein the first and second magnetic poles are disposed on opposite ends of the magnetic target so as to generate a uniform magnetic field, into the 180-degree angular position sensing range of the arc position encoder, and another one of the first and second magnetic poles out of the 180-degree angular position sensing range (400).

The processing module may further receive one or more proximity signals from one or more magnetic field sensors disposed within the base between the first and second ends, the one or more proximity signals indicating relative proximity of the one of the first and second magnetic poles within the 180-degree angular position sensing range of the arc position encoder to each of the one or more magnetic field sensors (402).

The processing module may still further determine the angular position of the rotating object within the 360-degree angular position range based at least in part on the one or more polarity transition signals and the one or more proximity signals (404).

In the above example, the one or more polarity transition sensors disposed on the one or more of the first and second ends of the base may comprise the one or more polarity transition sensors disposed within one or more of a first base extension disposed on the first end, wherein the first base extension extends from the first end, and a second base extension disposed on the second end, wherein the second base extension extends from the second end, in a similar manner as described above with reference to FIGS. 2 and 3. Furthermore, each of the one or more of the first and second base extensions may extend from the respective one of the first and second ends in a direction that substantially follows a circumference of the circle defined by the base, as also previously described.

Additionally, in some examples, to determine the angular position of the rotating object within the 360-degree angular position range based at least in part on the one or more polarity transition signals and the one or more proximity signals, the processing module may determine whether the angular position of the rotating object within the 360-degree angular position range corresponds to a first or a second 180-degree angular position sub-range of the 360-degree angular position range, based at least in part on the one or more polarity transition signals, wherein the first and second 180-degree angular position sub-ranges are non-overlapping consecutive angular position sub-ranges within the 360-degree angular position range. The processing module may further determine the angular position of the rotating object within the respective one of the first and second 180-degree angular position sub-ranges to which the angular position of the rotating object within the 360-degree angular position range corresponds, based at least in part on the one or more proximity signals.

In other examples, the processing module may determine one or more of an angular speed of the rotating object and a direction of angular rotation of the rotating object relative to the arc position encoder, based at least in part on the determined angular position of the rotating object within the 360-degree angular position range. For example, the processing module may determine the angular speed (e.g., in radians/second (ω), degrees/second, or revolutions per minute (RPM)) of the rotating object based on the determined angular position of the rotating object within the 360-degree angular position range at a particular first point in time, which may be referred to as a first angular position, as well as based on a second, different angular position of the rotating object within the 360-degree angular position range at a subsequent second point in time. In this example, the processing module may determine the angular speed of the rotating object by dividing a difference between the first and second angular positions (e.g., second angular position-first angular position=Δ (angular position), which is proportional to the angular distance traveled by the rotating object) by a difference between the first and second times (e.g., second time-first time=Δ (time), which equals the time elapsed). For example, to determine the angular speed of the rotating object, the processing module may utilize the following expression:

ω=Δ(angular position)/Δ(time) EQ. 1

Where ω corresponds to the angular speed of the rotating object, Δ (angular position) corresponds to a difference between the first and second angular positions, and Δ (time) corresponds to a difference between the first and second times. In other words, the angular speed of the rotating object may be expressed as a change in angular position of the rotating object over a unit of time.

In a similar manner, the processing module may determine the direction of angular rotation (e.g., clockwise or counterclockwise) of the rotating object relative to the arc position encoder based on the determined angular position of the rotating object within the 360-degree angular position range, which may once again be referred to as a first angular position, at a first point in time, by determining a second, different angular position of the rotating object within the 360-degree angular position range at a subsequent second point in time. In this example, the processing module may determine the direction of angular rotation by determining a sign of a difference between the first and second angular positions (e.g., sign of Δ (angular position), where Δ (angular position)=second angular position-first angular position). For example, to determine the direction of angular rotation of the rotating object, the processing module may utilize the following expression:

DIR=SIGN(Δ(angular position)) EQ. 2

Where DIR corresponds to the direction of angular rotation of the rotating object, Δ (angular position) corresponds to the difference between the first and second angular position values, and SIGN indicates a sign operator used to determine the sign of the difference between the first and second angular position values. Accordingly, the direction of angular rotation of the rotating object may be represented using a sign (e.g., “+” or “−”) that corresponds to the direction of angular rotation, which may, in turn, comprise one of e.g., a clockwise or a counterclockwise direction of rotation. In one example, DIR=“+” may correspond to a clockwise direction of angular rotation of the rotating object, and DIR=“−” may correspond to a counterclockwise direction of angular rotation of the rotating object. In other examples, different values of DIR may correspond to different directions of angular rotation of the rotating object.

Additionally, the processing module may determine the direction of angular rotation of the rotating object relative to the arc position encoder based at least in part on the one or more polarity transition signals. For example, as described above, the processing module may determine, based at least in part on the one or more polarity transition output signals, that a transition of one of the first and second magnetic poles into the 180-degree angular position sensing range of the arc position encoder, and another one of the first and second magnetic poles out of the 180-degree angular position sensing range, has occurred. As one example, the processing module may determine the direction of angular rotation of the rotating object based on, e.g., which of the first and second magnetic poles has transitioned into and out of the 180-degree angular position sensing range. As another example, the processing module may determine the direction of angular rotation of the rotating object based on one or more previously detected transitions (e.g., indications of which may be stored in one or more memories, or memory devices, within the angular position sensing system) of the first and second magnetic poles into and out of the 180-degree angular position sensing range, and the currently detected transition.

In some examples, the processing module may still further output one or more signals indicative of the determined angular position of the rotating object (406). As one example, the processing module may output a single signal indicative of the angular position of the rotating object over the 360-degree angular position sensing range, e.g., a value between 0 and 360 that is representative of the angular position of the rotating object within the 360-degree angular position range. Alternatively, as described above, the processing module may output a first signal indicative of whether the angular position of the rotating object within the 360-degree angular position range corresponds to a first or a second 180-degree angular position sub-range of the 360-degree angular position range. As also described above, the first and second 180-degree angular position sub-ranges may be non-overlapping consecutive angular position sub-ranges within the 360-degree angular position range. Additionally, processing module may further output a second signal indicative of the angular position of the rotating object within the respective one of the first and second 180-degree angular position sub-ranges to which the angular position of the rotating object within the 360-degree angular position range corresponds.

Furthermore, as also described above, to output the one or more “output” signals indicative of the determined angular position of the rotating object, the processing module may combine (e.g., level-shift) the angular position of each of the first and second magnetic poles over the 180-degree sensing range, as indicated by the one or more proximity signals from the one or more magnetic field sensors, to determine the angular position of the rotating object over the 360-degree angular position range. For example, the processing module may combine the one or more proximity signals generated by the one or more magnetic field sensors for each of the first and second magnetic poles to generate the one or more output signals.

In addition, the processing module may further process the one or more proximity signals, prior to, or after the combining, such as by performing any of a variety of filtering, level-shifting or translation, or other types of signal processing or conditioning, to generate the one or more output signals. Finally, to generate the one or more output signals, the processing module may still further linearize one or more of the one or more proximity signals and the angular position of the rotating object over the 360-degree angular position range, e.g., using any techniques applicable to linearization of output signals from a plurality of magnetic sensors. In other words, the one or more output signals may comprise a linearized signal indicative of the angular position of the rotating object over the 360-degree angular position range.

Finally, as described above, the processing module may further output the one or more output signals, and/or store the one or more output signals in the one or more memories, or memory devices, described above with reference to system 100 of FIG. 1.

In any case, the one or more output signals, whether represented as a single signal, or a plurality of signals, may comprise one or more analog signals, one or more digital signals, or any combination thereof.

The techniques of this disclosure may enable the angular position sensing system (e.g., angular position sensing system 100) including the arc position encoder (e.g., arc position encoder 108, 200, 300) and the processing module (e.g., processing module 112), as described above, to sense the angular position of the rotating object over the 360-degree angular position range. Accordingly, in contrast to other angular position sensing techniques which may be used to sense an angular position of a rotating object over a 360-degree angular position range, for example, techniques using a plurality of (e.g., two) arc position encoders each comprising a 180-degree angular position sensing range, or a relatively more complex full-range angular position encoder, the techniques of this disclosure may enable sensing the angular position of the rotating object over the 360-degree angular position range using a single arc position encoder comprising a 180-degree angular position sensing range.

In this manner, the method of FIG. 4 represents an example of a method of sensing an angular position of a rotating object over a 360-degree angular position range using an arc position encoder comprising a 180-degree angular position sensing range, the method comprising receiving one or more polarity transition signals from one or more polarity transition sensors disposed on one or more of a first end and a second end of a base of the arc position encoder, the one or more polarity transition signals indicating a transition of one of a first magnetic pole and a second magnetic pole of a magnetic target coupled to the rotating object so as to rotate about an axis of rotation located in a center of a circle defined by the base, wherein the first and second magnetic poles are disposed on opposite ends of the magnetic target so as to generate a uniform magnetic field, into the 180-degree angular position sensing range of the arc position encoder, and another one of the first and second magnetic poles out of the 180-degree angular position sensing range, receiving one or more proximity signals from one or more magnetic field sensors disposed within the base between the first and second ends, the one or more proximity signals indicating relative proximity of the one of the first and second magnetic poles within the 180-degree angular position sensing range of the arc position encoder to each of the one or more magnetic field sensors, and determining the angular position of the rotating object within the 360-degree angular position range based at least in part on the one or more polarity transition signals and the one or more proximity signals.

The techniques of this disclosure may be implemented in a wide variety of computer devices. Any components, units, or modules that have been described are provided to emphasize functional aspects, and do not necessarily require realization by different hardware units. The techniques described herein may also be implemented in hardware, software, firmware, or any combination thereof. Any features described as modules, units, or components may be implemented together in an integrated logic device, or separately as discrete but interoperable logic devices. In some cases, various features may be implemented as an integrated circuit device, such as an integrated circuit chip, or chipset.

If any aspect of the techniques are implemented in software, the techniques may be realized at least in part by a computer-readable storage medium comprising instructions that, when executed in a processor, performs one or more of the methods described above. The computer-readable storage medium may comprise a tangible computer-readable storage medium, and may form part of a larger product. The computer-readable storage medium may comprise random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The computer-readable storage medium may also comprise a non-volatile storage device, such as a hard-disk, magnetic tape, a compact disc (CD), digital versatile disc (DVD), Blu-ray disc, holographic data storage media, or other non-volatile storage device.

The memory, or memory devices, described herein, which may be used as part of the described techniques, may also be realized in any of a wide variety of memory, or memory devices, including but not limited to, RAM, SDRAM, NVRAM, EEPROM, FLASH memory, dynamic RAM (DRAM), magnetic RAM (MRAM), or other types of memory.

The term “processor” as used herein may refer to any of the foregoing structure or any other structure suitable for implementation of the techniques described herein. In addition, in some aspects, the functionality described herein may be provided within dedicated software modules or hardware modules configured for performing the techniques of this disclosure. Even if implemented in software, the techniques may use hardware such as a processor to execute the software, and a memory to store the software. In any such cases, the computers described herein may define a specific machine that is capable of executing the specific functions described herein. Also, the techniques could be fully implemented in one or more circuits or logic elements, which could also be considered a processor.

Various examples have been described. These and other examples are within the scope of the following claims.

What is claimed is:

1. An angular position sensing system for sensing an angular position of a rotating object over a 360-degree angular position range, the system comprising:
an arc position encoder comprising a 180-degree angular position sensing range, wherein the arc position encoder includes:
a base comprising an arc length defined by a first end and a second end of the base;
one or more magnetic field sensors disposed within the base between the first and second ends;
one or more of a first base extension disposed on the first end, wherein the first base extension extends from the first end, and a second base extension disposed on the second end, wherein the second base extension extends from the second end;
one or more polarity transition sensors disposed within the one or more of the first and second base extensions; and
a magnetic target comprising a first magnetic pole and a second magnetic pole disposed on opposite ends of the magnetic target so as to generate a uniform magnetic field, wherein the magnetic target is coupled to the rotating object so as to rotate about an axis of rotation located in a center of a circle defined by the base, and wherein, at any given time, one of the first and second magnetic poles is located within the 180-degree angular position sensing range of the arc position encoder, and another one of the first and second magnetic poles is located outside of the 180-degree angular position sensing range.

2. The angular position sensing system of claim 1, wherein the one or more magnetic field sensors are configured to sense relative proximity of the one of the first and second magnetic poles located within the 180-degree angular position sensing range of the arc position encoder to each magnetic field sensor of the one or more magnetic field sensors.

3. The angular position sensing system of claim 1, wherein the one or more polarity transition sensors are configured to sense a transition of one of the first and second magnetic poles into the 180-degree angular position sensing range of the arc position encoder, and another one of the first and second magnetic poles out of the 180-degree angular position sensing range.

4. The angular position sensing system of claim 1, wherein each of the one or more of the first and second base extensions extends from the respective one of the first and second ends in a direction that substantially follows a circumference of the circle defined by the base.

5. The angular position sensing system of claim 1, wherein the magnetic field sensors of the one or more magnetic field sensors are substantially uniformly spaced within the base between the first and second ends.

6. The angular position sensing system of claim 1, wherein the one or more magnetic field sensors and the one or more polarity transition sensors are substantially uniformly spaced within the base and the one or more of the first and second base extensions.

7. The angular position sensing system of claim 1, wherein each magnetic field sensor of the one or more magnetic field sensors comprises a magnetoresistive (MR) sensor.

8. The angular position sensing system of claim 1, wherein each polarity transition sensor of the one or more polarity transition sensors comprises a magnetoresistive (MR) sensor.

9. The angular position sensing system of claim 1, wherein each polarity transition sensor of the one or more polarity transition sensors comprises a Hall-Effect sensor.

10. The angular position sensing system of claim 1, wherein the one or more polarity transition sensors comprise one or more magnetoresistive (MR) sensors and one or more Hall-Effect sensors.

11. The angular position sensing system of claim 1, further comprising a processing module configured to:
determine one or more polarity transition output signals of the one or more polarity transition sensors;
determine one or more proximity output signals of the one or more magnetic field sensors; and
determine the angular position of the rotating object within the 360-degree angular position range, based at least in part on the one or more polarity transition output signals and the one or more proximity output signals.

12. The angular position sensing system of claim 11, wherein to determine the angular position of the rotating object within the 360-degree angular position range based at least in part on the one or more polarity transition output signals and the one or more proximity output signals, the processing module is configured to:
determine whether the angular position of the rotating object within the 360-degree angular position range corresponds to a first or a second 180-degree angular position sub-range of the 360-degree angular position range, based at least in part on the one or more polarity transition output signals, wherein the first and second 180-degree angular position sub-ranges are non-overlapping consecutive angular position sub-ranges within the 360-degree angular position range; and
determine the angular position of the rotating object within the respective one of the first and second 180-degree angular position sub-ranges to which the angular position of the rotating object within the 360-degree angular position range corresponds, based at least in part on the one or more proximity output signals.

13. The angular position sensing system of claim 11, wherein the processing module is further configured to determine one or more of an angular speed of the rotating object and a direction of angular rotation of the rotating object relative to the arc position encoder, based at least in part on the determined angular position of the rotating object within the 360-degree angular position range.

14. The angular position sensing system of claim 11, wherein the processing module is further configured to determine a direction of angular rotation of the rotating object relative to the arc position encoder, based at least in part on the one or more polarity transition output signals.

15. A method of sensing an angular position of a rotating object over a 360-degree angular position range using an arc position encoder comprising a 180-degree angular position sensing range, the method comprising:
receiving one or more polarity transition signals from one or more polarity transition sensors disposed on one or more of a first end and a second end of a base of the arc position encoder, the one or more polarity transition signals indicating a transition of one of a first magnetic pole and a second magnetic pole of a magnetic target coupled to the rotating object so as to rotate about an axis of rotation located in a center of a circle defined by the base, wherein the first and second magnetic poles are disposed on opposite ends of the magnetic target so as to generate a uniform magnetic field, into the 180-degree angular position sensing range of the arc position encoder, and another one of the first and second magnetic poles out of the 180-degree angular position sensing range;
receiving one or more proximity signals from one or more magnetic field sensors disposed within the base between the first and second ends, the one or more proximity signals indicating relative proximity of the one of the first and second magnetic poles within the 180-degree angular position sensing range of the arc position encoder to each of the one or more magnetic field sensors; and
determining the angular position of the rotating object within the 360-degree angular position range based at least in part on the one or more polarity transition signals and the one or more proximity signals.

16. The method of claim 15, wherein the one or more polarity transition sensors disposed on the one or more of the first and second ends of the base comprises the one or more polarity transition sensors disposed within one or more of a first base extension disposed on the first end, wherein the first base extension extends from the first end, and a second base extension disposed on the second end, wherein the second base extension extends from the second end.

17. The method of claim 16, wherein each of the one or more of the first and second base extensions extends from the respective one of the first and second ends in a direction that substantially follows a circumference of the circle defined by the base.

18. The method of claim 15, wherein determining the angular position of the rotating object within the 360-degree angular position range based at least in part on the one or more polarity transition signals and the one or more proximity signals comprises:
determining whether the angular position of the rotating object within the 360-degree angular position range corresponds to a first or a second 180-degree angular position sub-range of the 360-degree angular position range, based at least in part on the one or more polarity transition signals, wherein the first and second 180-degree angular position sub-ranges are non-overlapping consecutive angular position sub-ranges within the 360-degree angular position range; and
determining the angular position of the rotating object within the respective one of the first and second 180-degree angular position sub-ranges to which the angular position of the rotating object within the 360-degree angular position range corresponds, based at least in part on the one or more proximity signals.

19. The method of claim 15, further comprising:
determining one or more of an angular speed of the rotating object and a direction of angular rotation of the rotating object relative to the arc position encoder, based at least in part on the determined angular position of the rotating object within the 360-degree angular position range.

20. The method of claim 15, further comprising:
determining a direction of angular rotation of the rotating object relative to the arc position encoder, based at least in part on the one or more polarity transition signals.
